(19) United States
(12) Patent Application Publication
(10) Pub. No.: US 2011/0201208 A1
(43) Pub. Date: Aug. 18, 2011

(54) PLASMA ETCHING METHOD AND PLASMA ETCHING APPARATUS

(75) Inventors: Masato Kawakami, Yamanashi (JP); Sumie Nagaseki, Yamanashi (JP)

(73) Assignee: TOKYO ELECTRON LIMITED, Tokyo (JP)

(21) Appl. No.: 13/125,141

(22) PCT Filed: Oct. 19, 2009
(86) PCT No.: PCT/JP2009/068010

§ 371 Date: Apr. 20, 2011

(30) Foreign Application Priority Data
Oct. 20, 2008 (JP) 2008-269458

(51) Int. Cl. H01L 21/3065

(52) U.S. Cl. 438/714; 156/345.26; 257/E21.218

(57) ABSTRACT

According to one embodiment, a process gas containing a fluorocarbon-based gas being an etch gas having a deposition property and SF₆ gas as an additional gas are introduced into a process chamber, a plasma is generated in the process chamber, and an etching is performed on a silicon-containing oxide film formed on a substrate by using a resist pattern as a mask through the plasma. At this time, based on a relationship between an etch rate and a resist selectivity that is changed with respect to a change in a flow rate of the additional gas, the flow rate of the additional gas is set to a range of the flow rate in which changes in the etch rate and the resist selectivity accompanying an increase in the flow rate of the additional gas tend to increase.

### TECHNICAL FIELD

Embodiments described herein relate generally to a plasma etching method and a plasma etching apparatus; and, more particularly, to a plasma etching method and a plasma etching apparatus which are suitably applicable to a plasma etching process of a silicon-containing oxide film, particularly to a high aspect ratio contact (HARC) etching process.

### BACKGROUND

In a manufacturing process of a semiconductor device, a photoresist pattern is formed on a film to be etched, which is formed on a surface of a substrate, e.g., a semiconductor wafer (hereinafter, referred to as “wafer”) or a flat panel display (FPD), through a photographic process, and then the film is etched by using the photoresist pattern as a mask. In such an etching, a plasma etching apparatus is employed for forming a plasma of a process gas over a substrate that is disposed in a process chamber, and performing an etching process through any active species of ions or radicals in the plasma.

In recent years, with the high integration of semiconductor devices, the micronization of semiconductor devices has been progressing and micromachining is required in an etching process. Also, in a HARC etching process, a high aspect ratio is required due to holes or trenches that are formed on a film such as an oxide film to be etched.

When forming holes or trenches having such high aspect ratio, an etch gas, e.g., a fluorocarbon-based gas such as C₄F₈, C₄F₆, C₅F₈, or the like, having a deposition property as a process gas is typically used. With this etch gas, a film etching process may proceed while supplying a large amount of active species as well as promoting accumulation of a byproduct, e.g., a deposit of a carbon-based polymer or the like, due to etching. As such, it is possible to increase an etch rate and improve a resist selectivity.

However, since an etching process may stop depending on a film thickness of such deposit (DEPO), a film thickness of the deposit needs to be controlled so as to prevent the etching stoppage. In this fine control of the film thickness of the deposit, O₂ gas having a deposit removal function is typically utilized (for example, See Japanese Laid-Open Patent Publication No. 2003-264178). Specifically, a plasma is generated by adding O₂ gas to an etch gas having a deposition property such that an etching is promoted while removing an excessive deposit to control a film thickness thereof.

### SUMMARY

As the demand for miniaturization of semiconductor devices increases, aspect ratios of holes or trenches formed in an oxide film become increasingly larger, requiring higher etch rates.

As described above, when performing a plasma etching process by adding O₂ gas to an etch gas having a deposition property, as performed in the art, an etch rate can be improved by increasing a flow rate of the O₂ gas. As a flow rate of O₂ gas is increased, however, an etch rate of a film to be etched tends not to increase any longer when the flow rate is greater than a predetermined value. In this regard, an etch rate on a photoresist pattern tends to increase as much as the increased flow rate of the O₂ gas. Therefore, even though the flow rate of the O₂ gas is increased, when an etch rate is greater than a predetermined value, the etch rate of the film to be etched may not increase, and a resist selectivity may deteriorate. As a result, level of improvements in an etch rate and a resist selectivity are limited through only the increase of the flow rate of the O₂ gas.

In order to overcome the above limitation, upon performing a high aspect ratio etching process through an etch gas having a deposition property, inventors of the present invention have observed that SF₆ gas, which has been used for another purpose, is a good substitute for O₂ gas being typically used, for the purpose of controlling a deposit accumulated on a substrate to be processed.

SF₆ gas has a high ratio of fluorine atoms (F) such that, by taking into account this characteristic only, it has been typically used for suppressing roughness of a photoresist or cleaning deposits in a process chamber (for example, See Japanese Laid-Open Patent Publication Nos. 2005-72518 and 2006-32721). Moreover, in a typical plasma etching process, it is known that there is a tendency for an etch rate to be higher when a resist selectivity is lower, as F is increased (i.e., fluorine-rich). Thus, gas such as SF₆ having a high ratio of F has been considered not to be suitable as an additional gas in an etching process required for a high resist selectivity.

However, the inventors of the present invention discovered through repetitive experiments that by adding SF₆ gas of a regulated flow rate to a fluorocarbon-based gas serving as an etch gas having a deposition property, both an etch rate and a resist selectivity are improved compared to using O₂ gas as an additional gas.

It is, therefore, an object of the present disclosure to provide a plasma etching method capable of improving both an etch rate and a resist selectivity upon performing a high aspect ratio etching process.

In accordance with a first aspect of the present disclosure, there is provided a plasma etching method comprising: disposing a substrate having a silicon-containing oxide film formed thereon in a process chamber; introducing a process gas containing a fluorocarbon-based gas being an etch gas having a deposition property and SF₆ gas as an additional gas into the process chamber, thereby generating a plasma; and etching the silicon-containing oxide film by using a resist pattern as a mask through the plasma, wherein, based on a relationship between an etch rate and a resist selectivity that is changed with respect to a change in a flow rate of the additional gas, the flow rate of the additional gas is set to a range of the flow rate in which changes in the etch rate and the resist selectivity accompanying an increase in the flow rate of the additional gas tend to increase.

In accordance with a second aspect of the present invention, there is provided a plasma etching apparatus that generates a plasma of gas in a process chamber and performs an etching on a silicon-containing oxide film formed on a substrate by using a resist pattern as a mask, the apparatus comprising: a process gas supply mechanism configured to supply a process gas containing a fluorocarbon-based gas to the process chamber; an additional gas supply mechanism configured to supply SF₆ gas as an additional gas to the process chamber; and a control unit configured to control at least the process gas supply mechanism and the additional gas supply mechanism, wherein the control unit is configured to introduce a process gas containing a fluorocarbon-based gas being an etch gas having a deposition property, and to introduce a SF₆ gas as an additional gas, into the process chamber, thereby generating a plasma, and control flow rates of the respective process gas and additional gas to respective predetermined values upon performing the etching on the silicon-containing oxide film by using the resist pattern as the mask, and based on a relationship between an etch rate and a resist selectivity that is changed with respect to a change in a flow rate of the additional gas, the predetermined value of the additional gas is set to a range of the flow rate of the additional gas in which changes in an etch rate and a resist selectivity accompanying an increase in the flow rate of the additional gas tend to increase.

The SF₆ gas is added as the additional gas to the process gas containing the fluorocarbon-based gas serving as the etch gas having a deposition property, and then the plasma of the process gas containing the SF₆ gas added thereto is formed, thereby performing an etching process on a film to be etched that is formed on a substrate. As such, by using the etch gas having a deposition property, the etching process proceeds while a deposit is accumulated as an etching product on a substrate to be processed.

At this time, by using the SF₆ gas in the additional gas, a film thickness of a deposit is effectively controlled mainly by an action of F (fluorine atom) depending on a flow rate of the SF₆ gas, such that an etch rate can be increased compared to using the O₂ gas. Moreover, hardness of a deposit is effectively controlled mainly by an action of S (sulfur atom), such that a resist selectivity can be further increased compared to using the O₂ gas. In this way, both the etch rate and the resist selectivity may be further increased than the typical manner and also holes or trenches of high aspect ratios are more effectively formed than the typical manner.

Furthermore, the flow rate of the additional gas is determined based on a relationship between an etch rate and a resist selectivity that is changed with respect to a change in a flow rate of the additional gas. Specifically, it is preferable that a flow rate of an additional gas may be set to a range of the flow rate of the additional gas in which changes in the etch rate and the resist selectivity are increased according to the increase of the flow rate of the additional gas. The above relationship between an etch rate and a resist selectivity may be obtained in advance through experiment, for example. In this way, an appropriate range of the flow rate of the additional gas may be easily obtained. Although such an appropriate range of the flow rate of the additional gas may depend on the kind of process gas, particularly, a fluorocarbon-based gas, it is preferable that a range of the flow rate of the additional gas is set to be 70% or less of the range of the flow rate of the fluorocarbon-based gas.

Further, in the relationship of the changes in the etch rate and the resist selectivity with respect to the change in the flow rate of the additional gas, it is preferable that the flow rate of the additional gas is set to be a maximum value in the flow rate range, that is, corresponding to a value at a transition point where a change in the resist selectivity accompanying the increase in the flow rate of the additional gas is transitioned from an increased tendency to a decreased tendency. As such, an optimal flow rate of the additional gas may be set to be values at which both the etch rate and the resist selectivity have maximum values.

Furthermore, O₂ gas may be added as the additional gas to the SF₆ gas. In this way, a fine control of a film thickness of a deposit can be easily accomplished through a flow rate of the O₂ gas. That is, the O₂ gas has a low capability of removing the deposit when compared with the SF₆ gas such that the fine control of the film thickness of the deposit can be easily accomplished by using an additional gas containing the O₂ gas.

Moreover, in some embodiments, when a fluorocarbon-based raw material used as the etch gas is in a liquid state at a room temperature, the liquid raw material may be evaporated through an evaporator to be supplied to the process chamber. Since a deposition property of the fluorocarbon-based gas becomes higher as an F/C ratio (i.e., a ratio of the number of fluorine atoms (F) to the number of carbon atoms (C)) becomes lower, the fluorocarbon-based gas may be suitable for a high aspect ratio etching process while some fluorocarbon-based gases may be in a liquid state at a room temperature. These liquid fluorocarbon-based raw materials are similarly evaporated through the evaporator to be used as an etch gas. The larger amount of deposits the fluorocarbon-based gas produces, the more enhanced effect the fluorocarbon-based gas provides when the SF₆ gas is added.

In the present disclosure, it is assumed that 1 mTorr is (10⁻³×101325/760) Pa and 1 sccm is (10⁻⁶/60) m³/sec.

### BRIEF DESCRIPTION OF THE DRAWINGS

FIG. 1 is a cross-sectional diagram showing a schematic configuration of a plasma etching apparatus in accordance with an embodiment of the present disclosure.

FIG. 2 is a graph showing the effect of an F/C ratio of a fluorocarbon-based gas affecting on an etching in accordance with the embodiment of the present disclosure.

FIG. 3 is a graph showing the relationship between a flow rate and an etch rate of SF₆ gas when a plasma etching is performed on a silicon oxide film by using the SF₆ gas as an additional gas.

FIG. 4 is a graph showing the relationship between a flow rate and an etch rate of SF₆ gas when a plasma etching is performed on a photoresist film by using the SF₆ gas as an additional gas.

FIG. 5 is a graph showing the relationship between a flow rate and an etch rate of O₂ gas when a plasma etching is performed on a silicon oxide film by using the O₂ gas as an additional gas.

FIG. 6 is a graph showing the relationship between a flow rate and an etch rate of O₂ gas when a plasma etching is performed on a photoresist film by using the O₂ gas as an additional gas.

FIG. 7 is a graph showing the relationship between an etch rate and a resist selectivity of a silicon oxide film for the purpose of comparing an etch property of O₂ gas with that of SF₆ gas when these gases are used as an additional gas.

### DETAILED DESCRIPTION

Illustrative embodiments of the present invention will now be described in detail with reference to the accompanying drawings. In the present disclosure and the accompanying drawings, components having substantially the same functions are given the same reference numerals such that a repetitive description will be omitted.

(Configuration Embodiment of Plasma Etching Apparatus)

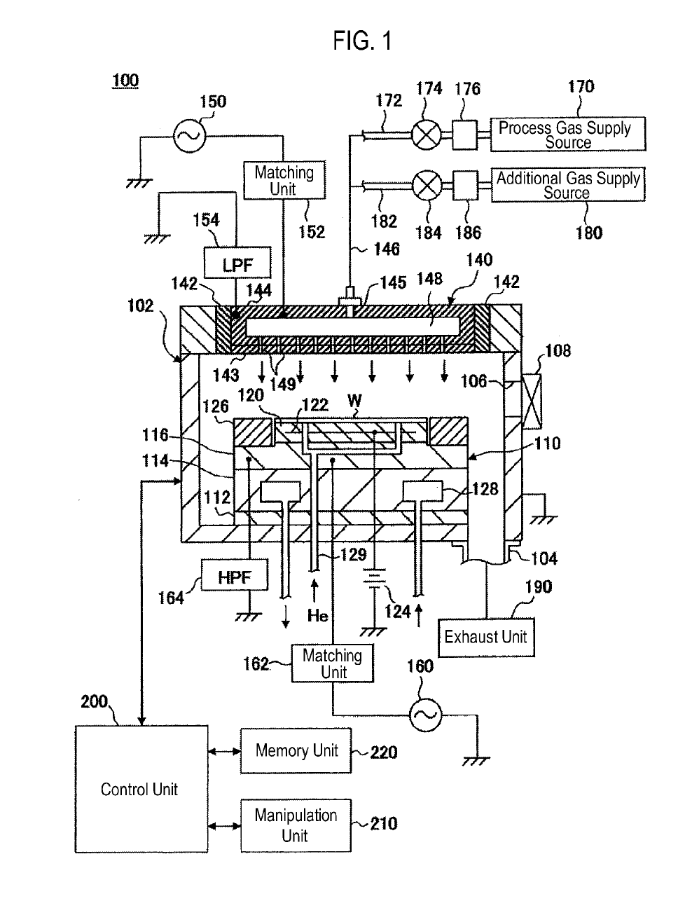

Initially, a configuration embodiment of a plasma etching apparatus in accordance with the present invention will be described. FIG. 1 shows a cross-sectional diagram of a schematic configuration of a plasma etching apparatus 100 in accordance with an embodiment of the present invention. As an example of the plasma etching apparatus 100, an inductively coupled plasma etching apparatus of a parallel-plate type electrode structure, which is capable of performing a high aspect ratio etching process, will be described.

As shown in FIG. 1, the plasma etching apparatus 100 includes a process chamber 102 constituted by a processing vessel of an approximately cylindrical shape. The process chamber 102 is formed with, e.g., an aluminum alloy and an inner wall surface of the process chamber 102 is coated with, e.g., an alumina film. The process chamber 102 is grounded.

A lower electrode 110 is provided at a lower portion of the process chamber 102. The lower electrode 110 is provided with a susceptor support114 of a column shape, which is disposed at the lower portion by interposing an insulating plate 112 made of ceramics and the like, and a susceptor 116 disposed on the susceptor support 114. The susceptor 116 constitutes a main body of the lower electrode 110 and a wafer W is mounted over the susceptor 116. Therefore, the lower electrode 110 may serve as a mounting table for mounting the wafer W.

An electrostatic chuck 120, which sucks and holds the wafer W with an electrostatic force, is disposed on an upper surface of the susceptor 116. The electrostatic chuck 120 is constituted by inserting an electrode 122 made of a conductive film into a pair of insulating films or insulating sheets and a DC (Direct Current) power source 124 is electrically connected to the electrode 122. Upon applying a DC voltage from the DC power source 124 to the electrode 122, an electrostatic force is generated on an upper surface of the electrostatic chuck 120 to suck and hold the wafer W.

On the upper surface of the susceptor 116, a focus ring (compensation ring) 126 for improving an etching uniformity is disposed to enclose the surroundings of the electrostatic chuck 120 and the wafer W. The focus ring 126 is made of a conductive member (for example, silicon).

In the susceptor support 114, a coolant chamber 128 is disposed on, e.g., a circumference. In the coolant chamber 128, a coolant (e.g., cooling water) from a chiller unit (not shown) disposed at the outside circulates to be supplied. A process temperature of the wafer W on the susceptor 116 is controlled according to a temperature of the coolant.

In the susceptor support 114, a heat transfer gas (e.g., He gas) from a heat transfer gas supply mechanism (not shown) is supplied between the upper surface of the electrostatic chuck 120 and a rear surface of the wafer W through a heat transfer gas supply line 129.

Also, the lower electrode 110 is not limited to the configuration shown in FIG. 1, and it may be constituted by interposing, e.g., a bellows made of aluminum between the insulating plate 112 and a bottom surface of the process chamber 102, to thereby be moved up and down through an elevation mechanism (not shown). By using this mechanism, a gap between the lower electrode 110 and an upper electrode 140 can be suitably controlled.

The upper electrode 140 is disposed parallel to and facing the lower electrode 110 in an upward direction thereof. A space formed between the upper electrode 140 and the lower electrode 110 is a plasma generation space. The upper electrode 140 is supported on a roof of the process chamber 102 through an insulation shielding member 142.

The upper electrode 140 is mainly constituted by an electrode plate 143 and an electrode support 144 which detachably supports the electrode plate 143. A gas inlet 145 for introducing gases (e.g., a process gas and an additional gas which are to be described later) into the process chamber 102 is disposed in the electrode support 144. As a process gas supply mechanism for supplying a process gas containing a deposition-etch gas, a process gas supply source 170 is connected to the gas inlet 145 through a process gas supply conduit 172. Further, as an additional gas supply mechanism for supplying an additional gas that controls deposits (depositions) being etch byproducts, an additional gas supply source 180 is connected to the gas inlet 145 through an additional gas supply conduit 182.

Specifically, the process gas supply conduit 172 and the additional gas supply conduit 182 are respectively connected to the gas inlet 145 through a gas supply conduit 146. As such, a process gas from the process gas supply conduit 172 and an additional gas from the additional gas supply conduit 182 join at the gas supply conduit 146 to be supplied to the gas inlet 145.

Opening/closing valves 174 and 184 and mass flow controllers 176 and 186 serving as a flow rate controller for controlling a flow rate of gas are disposed at the process gas supply conduit 172 and the additional gas supply conduit 182, respectively. Examples of the process gas and the additional gas are described later herein.

A gas diffusion chamber 148 having, e.g., a substantially cylindrical shape, is disposed in the electrode support 144 to uniformly diffuse the gas introduced from the gas supply conduit 146. A plurality of gas discharge holes 149 for discharging the gas from the gas diffusion chamber 148 into the process chamber 102 are formed on a lower portion of the electrode support 144 and the electrode plate 143. In this way, the gas diffused in the gas diffusion chamber 148 may be uniformly discharged from the gas discharge holes 149 toward the plasma generation space. Therefore, the upper electrode 140 may serve as a shower head for supplying gas into the process chamber 102.

In FIG. 1, the process gas supply mechanism and the additional gas supply mechanism, which are separated from each other, are shown as an illustrative embodiment, but they are not limited thereto. For example, in some embodiments, when many types of gases as a process gas are supplied, a number of process gas supply mechanisms may be employed. Similarly, in some embodiments, when many types of gases as an additional gas are supplied, a number of additional gas supply mechanisms may be employed. Examples of the process gas and the additional gas are described later herein.

Moreover, the upper electrode 140 shown in FIG. 1 is illustrated as a configuration of, e.g., a pre-mix type that pre-mixes the process gas and the additional gas to supply the same into the process chamber 102, but, in some embodiments, it may be constituted with a configuration of a post-mix type that supplies individual gases separately.

In the present embodiment, the electrode support 144 of the upper electrode 140 is made of a conductive material (for example, aluminum having an anodic-oxidized surface) and provided with a water cooling structure (not shown). The electrode plate 143 may be made of a conductor or semiconductor of a low resistance with low Joule heat, for example, a silicon-containing material. An example of such material includes, e.g., silicon or SiC.

A first high-frequency power source (upper high-frequency power source) 150 is electrically connected to the upper electrode 140 through a matching unit 152. The first high-frequency power source 150 outputs a high-frequency power (upper high-frequency power) having a frequency of 13.56 MHz or more, for example, 60 MHz. The magnitude of the high-frequency power of the first high-frequency power source 150 may be variable.

The matching unit 152 is configured to match a load impedance to an internal (or output) impedance of the first high-frequency power source 150 such that it serves to perceptually harmonize the output impedance of the first high-frequency power source 150 with the load impedance when a plasma is generated in the process chamber 102.

A second high-frequency power source (lower high-frequency power source) 160 is electrically connected to the susceptor 116 of the lower electrode 110 through a matching unit 162. A high-frequency power is supplied from the second high-frequency power source 160 to the susceptor 116 such that ions are attracted toward the wafer W. The second high-frequency power source 160 outputs a high-frequency power (lower high-frequency power) having a frequency ranging from 300 kHz to 13.56 MHz, for example, 2 MHz. The magnitude of the high-frequency power of the second high-frequency power source 160 may be variable.

The matching unit 162 is configured to match a load impedance to an internal (or output) impedance of the second high-frequency power source 160 such that it serves to perceptually harmonize the output impedance of the second high-frequency power source 160 with the load impedance when a plasma is generated in the process chamber 102.

A low-pass filter (LPF) 154 is electrically connected to the upper electrode 140. The LPF 154 is configured to block a high-frequency wave form the first high-frequency power source 150 and pass a high-frequency wave from the second high-frequency power source 160 to a ground. The LPF 154 is preferably made of an LR filter or LC filter. However, in some embodiments, it may be sufficient to employ only one conducting wire since only one single conducting wire can provide a high enough reactance for the high-frequency wave from the first high-frequency power source 150. Meanwhile, a high-pass filter (HPF) 164 is electrically connected to the susceptor 116 of the lower electrode 110 to pass the high-frequency wave from the first high-frequency power source 150 to the ground.

An exhaust outlet 104 is formed on the bottom of the process chamber 102 and an exhaust unit 190 constituted with a vacuum pump and the like is connected to the exhaust outlet 104. An interior of the process chamber 102 is exhausted through the exhaust unit 190 to be depressurized to a predetermined vacuum pressure.

Also, a carry-in/out port 106 for wafer W is disposed on a sidewall of the process chamber 102, and can be opened and closed by a gate valve 108. Further, in some embodiments, a deposition shield (not shown) may be detachably disposed on an inner wall of the process chamber 102 so as to prevent an etch byproduct (deposition) from being attached to the process chamber 102.

Each of the components of the plasma etching apparatus 100 is connected to and controlled by a control unit (overall control system) 200. Also, a manipulation unit 210 is connected to the control unit 200. The manipulation unit 210 may be constituted with a keyboard for inputting commands from an operator to manage the plasma etching apparatus 100, a display for visualizing and displaying operation statuses of the plasma etching apparatus 100, and the like.

Moreover, a memory unit 220 is connected to the control unit 200. The memory unit 220 is configured to store programs for realizing various processes performed in the plasma etching apparatus 100 under the control of the control unit 200, recipe data required for executing the programs, or the like.

For example, the memory unit 220 may store recipes for performing necessary processes such as a process recipe for performing process treatments, e.g., a plasma etching and an ashing of a wafer, and a cleaning recipe for cleaning an interior of a process chamber, and the like. These recipes relate to a plurality of parameters such as a control parameter for controlling each component of the plasma etching apparatus 100, a setting parameter, and the like. The process recipe may comprise parameters such as a process gas, a flow rate of an additional gas, a pressure in a process chamber, an upper high-frequency power, a lower high-frequency power, a temperature of an upper electrode, a temperature of a lower electrode, and the like.

Also, in some embodiments, these recipes may be stored in a hard disk or a semiconductor memory, and further set in a predetermined position of the memory device 220 while being accommodated within a portable-computer readable storage medium such as a CD-ROM, a DVD, and the like.

The control unit 200 is configured to read out a desired process recipe from the memory unit 220 based on commands from the manipulation unit 210 and configured to control the components, thereby performing a desired process in the plasma etching apparatus 100. Also, the control unit 200 is configured to edit the recipes in response to inputs from the manipulation unit 210.

(Plasma Etching Method)

A plasma etching method is described herein, which is executed in the plasma etching apparatus, in accordance with an embodiment of the present invention. In the present embodiment, a wafer W where a photoresist pattern is formed on a film to be etched (e.g., a silicon oxide film) over a silicon base material is used. A pattern of holes or trenches is formed on the photoresist pattern and the film is etched by using the photoresist pattern as a mask. Beside the silicon oxide film, the film to be etched may include a silicon nitride film, a silicon carbide film, a poly silicon film, an interlayer low-k (low dielectric constant) film, and the like.

When a plasma etching is performed on this wafer W by using the plasma etching apparatus 100, the gate valve 108 is first opened and the wafer W is carried in and mounted on the lower electrode 110 to be sucked and held by the electrostatic chuck 120. The gate valve 108 is then closed. As the interior of the process chamber 102 is exhausted through the exhaust unit 190 to be depressurized to a predetermined vacuum pressure, a process gas from the process gas supply source 170 and an additional gas from the additional gas supply source 180 are respectively introduced into the process chamber 102 in a predetermined amount. At this time, for effectively cooling the wafer W, a heat transfer gas (for example, He gas) is supplied to a rear surface of the wafer W through the heat transfer gas supply line 129 to control the upper electrode 140, the lower electrode 110, and the sidewall of the process chamber 102 to a predetermined temperature.

And, an upper high-frequency power (60 MHz) is applied from the first high-frequency power source 150 to the upper electrode 140 as well as a lower high-frequency power (2 MHz) is supplied to the lower electrode 110. In this way, a plasma of the process gas and the additional gas is generated in a plasma generation space over the wafer W and a plasma etching is performed on the film to be etched over the wafer W.

As for etching conditions, it is preferable that the upper high-frequency power is, e.g., 500 W to 3500 W, the lower high-frequency power is, e.g., 100 W to 2500 W, a pressure in the process chamber 102 is, e.g., 15 mTorr, and a temperature of the wafer W is, e.g., −20 degrees Celsius to 100 degrees Celsius.

Also, when a high aspect ratio contact (HARC) is formed according to the present embodiment, it is preferable to use an etch gas having a deposition property as the additional gas. For the etch gas having a deposition property, a fluorocarbon-based gas such as C₄F₈, C₄F₆, C₅F₈ and the like, may be used. With these gases, an etching can be performed on the film to be etched while supplying a large amount of active species such as CF-based radials (CF*, CF₂*, CF₃*) and promoting an accumulation of a deposit (deposition) made of, e.g., a fluorocarbon-based polymer (CF-based polymer) as an etch byproduct on the wafer W. Thereby, an etch rate can be higher and a resist selectivity can be improved.

However, because an etching may stop depending on a film thickness of a deposit that is accumulated on the wafer W, it is required to control the film thickness of the deposit so as to prevent the etching stoppage. The fluorocarbon-based gas is a CₓF_{y} gas containing C (carbon atom) and F (fluorine atom), for example. In such fluorocarbon-based gas, an etch rate becomes higher as C is decreased and F is increased (F-rich) while a deposit of a CF-based polymer is easily accumulated on the wafer W as C is increased and F is decreased (C-rich). An amount of deposit varies depending on a ratio of C and F (i.e., an F/C ratio) such that there is a tendency to easily proceed or stop an etching according to the F/C ratio.

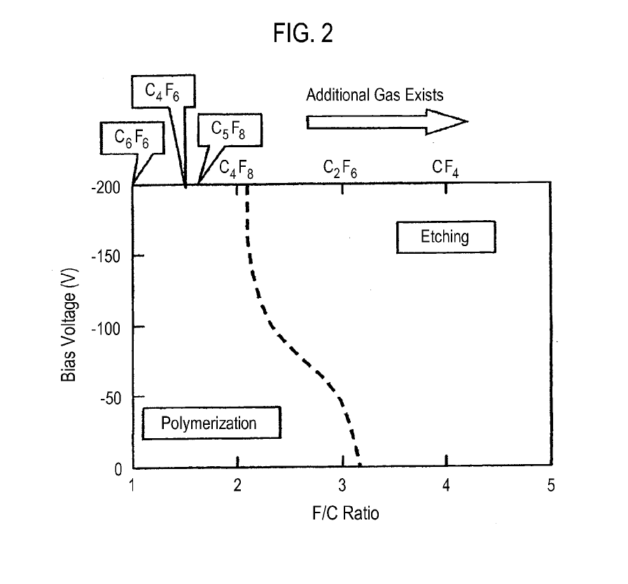

With reference to FIG. 2, the effect of an F/C ratio of a fluorocarbon-based gas affecting on an etching will be described. FIG. 2 is a graph showing the effects of an F/C ratio and a self-bias voltage, which is generated on the wafer W, affecting an etching. As shown in FIG. 2, if gas has a low F/C ratio, a deposit is increased such that an etch rate becomes lower. Contrary to this, if gas has a high F/C ratio, a deposit is decreased such that an etch rate becomes higher. However, when the deposit is excessively increased, an etch stop occurs such that an etching does not proceed any more. In FIG. 2, a boundary at which such an etch stop occurs is shown as a dotted line.

According to the above, CF₄ (an F/C ratio of 4) has a high ratio of F than C such that an etching may proceed at a high etch rate even with CF₄ only. However, the deposit of CF₄ is generated in a very small amount such that CF₄ is not suitable for a high aspect ratio etching. On the other hand, C₄F₆ (an F/C ratio of 1.5) and C₅F₈ (an F/C ratio of 1.6) generate a large amount of deposits such that they are suitable for a high aspect ratio etching. Therefore, in the present embodiment, it is preferable to use a fluorocarbon-based gas having an F/C ratio of 3 or less as an etch gas.

This fluorocarbon-based gas has a lower F/C ratio such that an etching may not proceed at a high etch rate. Therefore, by adding O₂ gas or SF₆ gas as an additional gas to an etch gas having such deposition property, the characteristics of the etch gas can be shifted to an arrow direction in FIG. 2 to thereby increase an etch rate.

The action of this additional gas is as follows. When a typical O₂ gas is added as an additional gas, a chemical reaction, e.g., O₂+C→CO₂, may proceed to reduce C while increasing F such that an F/C ratio can be increased. Also, a film thickness of a deposit can be decreased due to a deposit removal action of the O₂ gas to thereby increase an etch rate.

However, when the O₂ gas is excessively added, the film thickness of the deposit becomes extremely thin and a decrease amount of C becomes higher. Since C causes a decrease of O in an oxide film that is a film to be etched, an etching does not proceed if the decrease of O becomes high. Therefore, even though the O₂ gas is increased, if an etch rate of the film to be etched passes over a certain point, there is a tendency that it little increases.

When SF₆ gas is added as an additional gas, F is increased such that the F/C ratio moves to the increase direction. Also, since the SF₆ gas has a high ratio of F, such that F is dramatically increased against C and further a deposit removal action of the SF₆ gas is greater than that of the O₂ gas. As such, an etch rate can be dramatically increased when compared with the O₂ gas. Moreover, upon using the SF₆ gas, a decrease of C can be suppressed when compared with using the O₂ gas such that an increase tendency of an etch rate is continually maintained up to a higher level than that of the O₂ gas when a flow rate of the SF₆ gas is increased.

However, the SF₆ gas has a very high ratio of F (fluorine atom). Thus, in the prior art, attention has been paid primarily this property of the SF₆ gas such that the SF₆ gas has been typically used, for example, to suppress a roughness of a photoresist or to clean a deposit in a process chamber. Also, in plasma etching, it is known that there is a tendency for an increase of F (fluorine atom) (fluorine-rich) to cause an etch rate to be high while causing a resist selectivity to be low. Therefore, it has been generally considered in the prior art that a gas having a high ratio of F as the SF₆ gas cannot be used as an additional gas in an etching process for which a high selectivity is required.

On the contrary, the inventors of the present invention discovered through experiments that when SF₆ gas regulated at an appropriate flow rate is added to a fluorocarbon-based gas, an etch rate can be dramatically improved and a resist selectivity can also be improved in comparison with using O₂ gas as the additional gas.

Therefore, in the present embodiment, as an etch gas having a deposition property serving as an additional gas, SF₆ gas as well as a fluorocarbon-based gas such as C₄F₈, C₄F₆, or C₅F₈ having an F/C ratio of 3 or less are used. Also, in some embodiments, a rare gas such as Ar gas may be added to a process gas. By adding the Ar gas to the process gas, electrons and ions in a plasma can be increased such that a plasma density can be increased.

Also, among fluorocarbon-based gases having a low F/C ratio, there is, for example, C₆F₆ which is in a liquid state at a room temperature. In such a case, it is preferable that the process gas supply source 170 is constituted with, for example, a liquid raw material supply source and an evaporator, and a liquid raw material such as C₆F₆, which is supplied from the liquid raw material supply source, is evaporated to be introduced into the process chamber 102.

(Experiments for Verifying the Effect of Additional Gas)

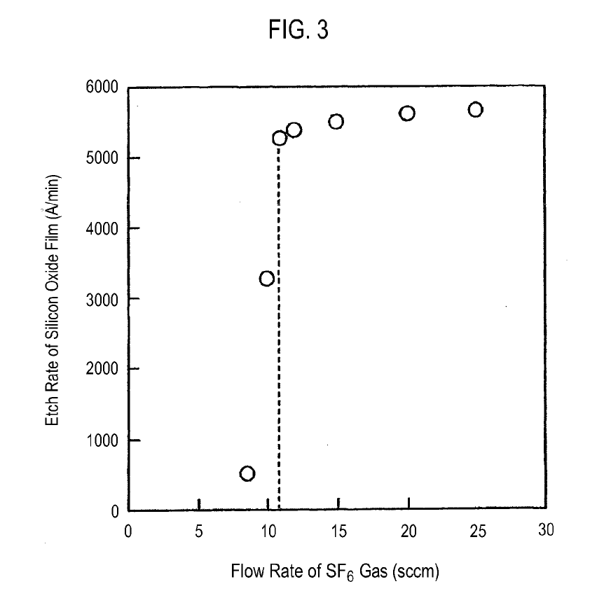

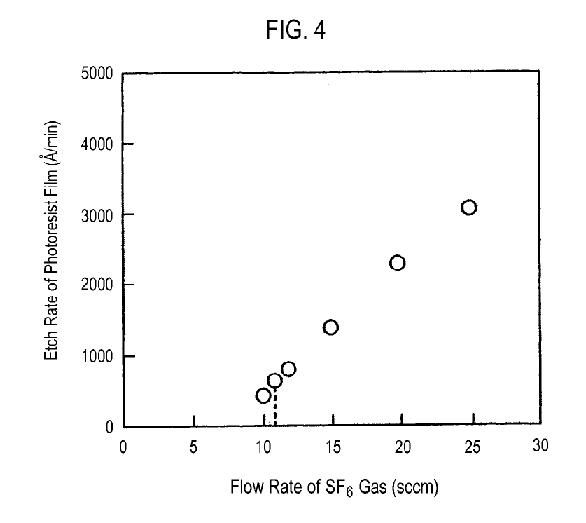

With reference to the accompanying drawings, descriptions will be made regarding the results of experiments for verifying an effect when using a fluorocarbon-based gas as an etch gas and SF₆ gas as an additional gas that is added to the etch gas. Initially, the results of experiments are plotted in FIGS. 3 and 4 when performing a plasma etching by using C₄F₆ gas and Ar gas as a process gas and SF₆ gas as an additional gas.

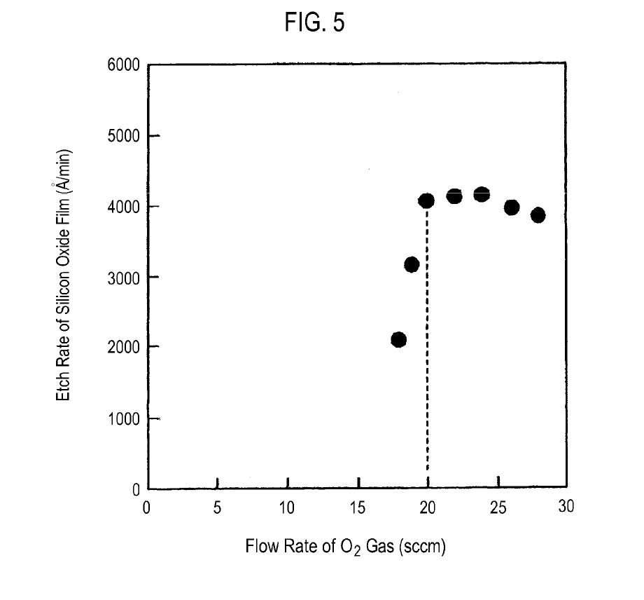

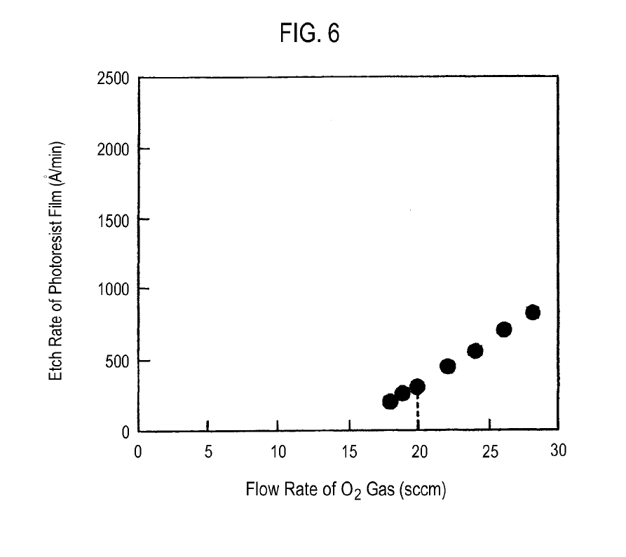

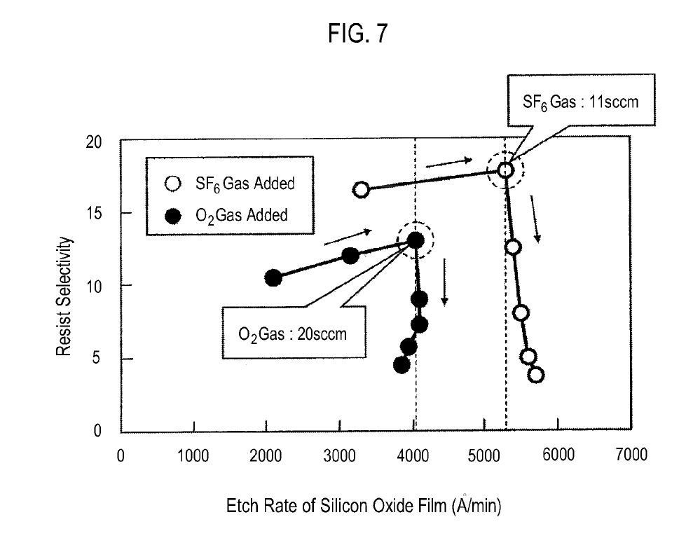

Also, as a comparative example, the results of experiments are plotted in FIGS. 5 and 6 when performing the above plasma etching by using O₂ gas as the additional gas instead of the SF₆ gas. FIG. 7 is a graph showing etching characteristics against a flow rate of an additional gas, i.e., a relationship between an etch rate of a silicon oxide film and a resist selectivity (the etch rate of the silicon oxide film/an etch rate of a photoresist film) when using the SF₆ gas (white circle) and the O₂ gas (black circle) as the additional gas, based on the results of FIGS. 3 to 6.

FIG. 3 shows a graph indicative of a relationship between a flow rate and an etch rate of the SF₆ gas upon etching a silicon oxide film formed on the wafer W. In the experiment shown in FIG. 3, flow rates of the C₄F₆ gas and the Ar gas are fixed to 22 sccm and 300 sccm, respectively, and a plasma etching is performed by changing a flow rate of the SF₆ gas to 8 sccm, 10 sccm, 11 sccm, 12 sccm, 15 sccm, 20 sccm, and 25 sccm. Further, a wafer in-surface distribution of respective etch rates is measured and an average of the respective measured results is calculated and then plotted on the graph.

FIG. 4 shows a graph indicative of a relationship between a flow rate and an etch rate of the SF₆ gas upon etching a photoresist film formed on the wafer W. In the experiment shown in FIG. 4, flow rates of the C₄F₆ gas and the Ar gas are fixed to 22 sccm and 300 sccm, respectively. Further, a plasma etching is performed by changing a flow rate of the SF₆ gas to 10 sccm, 11 sccm, 12 sccm, 15 sccm, 20 sccm, and 25 sccm to measure a wafer in-surface distribution of respective etch rates and calculate an average of the respective measured results. The calculated averages are plotted on the graph.

FIG. 5 shows a graph indicative of a relationship between a flow rate and an etch rate of the O₂ gas upon etching the silicon oxide film formed on the wafer W. In the experiment shown in FIG. 5, flow rates of the C₄F₆ gas and the Ar gas are fixed to 22 sccm and 300 sccm, respectively, and a plasma etching is performed by changing a flow rate of the O₂ gas to 18 sccm, 19 sccm, 20 sccm, 22 sccm, 24 sccm, 26 sccm, and 28 sccm to measure a wafer in-surface distribution of respective etch rates and calculate an average of the measured results. The calculated averages are plotted on the graph.

FIG. 6 shows a graph indicative of a relationship between a flow rate and an etch rate of the O₂ gas upon etching the photoresist film formed on the wafer W. In the experiment shown in FIG. 6, flow rates of the C₄F₆ gas and the Ar gas are fixed to 22 sccm and 300 sccm, respectively, and a plasma etching is performed by changing a flow rate of the O₂ gas to 18 sccm, 19 sccm, 20 sccm, 22 sccm, 24 sccm, 26 sccm, and 28 sccm to measure a wafer in-surface distribution of respective etch rates and calculate an average of the measured results. The calculated averages are plotted on the graph.

Additional conditions in these experiments are provided as follows.

[Etching Conditions]

Pressure in Process Chamber: 15 mTorr

High-Frequency Power to Upper-Portion: 2000 W

High-Frequency Power to Lower-Portion: 1500 W

Upper Electrode Temperature: 60 degrees Celsius

Lower Electrode Temperature: 0 degrees Celsius

Sidewall Temperature: 50 degrees Celsius

Center Pressure of Heat Transfer Gas: 10 Torr

Edge Pressure of Heat Transfer Gas: 35 Torr

According to the experiments shown in FIGS. 3 and 5, the etch rate of the silicon oxide film remains around 4000 angstrom/min as shown in FIG. 5 when the O₂ gas at a flow rate of 20 sccm or more is used as the additional gas. Otherwise, when the SF₆ gas at a flow rate of 11 sccm or more is used as the additional gas, the etch rate of the silicon oxide film remains in the range of 5000 to 6000 angstrom/min as shown in FIG. 3. Therefore, it can be noted that an extremely high etch rate of the silicon oxide film is obtained by using the SF₆ gas rather than the O₂ gas.

Also, when the SF₆ gas is used, as shown in FIG. 3, the etch rate is drastically increased in a range equal to or lower than 5000 angstrom/min only by slightly increasing the flow rate of the SF₆ gas. However, it is gradually increased in a range over 5000 angstrom/min as the flow rate of the SF₆ gas increases while the variation of the etch rate is not very significant. Otherwise, when the O₂ gas is used, as shown in FIG. 5, an etch rate shows little change at a flow rate in the range of 20 sccm to 24 sccm while it is decreased as the flow rate is further increased. These tendencies show that the etch rate is increased as the flow rate of the SF₆ gas is increased while it is decreased as the flow rate of the O₂ gas is extremely increased.

According to the experiment results shown in FIGS. 4 and 6, when the O₂ gas is used as the additional gas, the etch rate of the photoresist film is gradually increased in the range of 200 to 800 angstrom/min as shown in FIG. 6. Otherwise, when the SF₆ gas is used as the additional gas, the etch rate of the photoresist film is gradually increased in the range of 200 to 1500 angstrom/min as shown in FIG. 4 such that it has a development slightly higher than when the O₂ gas is used, but the etch rate is little changed at a low flow rate (e.g., a range of 24 sccm or less for the O₂ gas and a range of 11 sccm or less for the SF₆ gas). Therefore, since the etch rate of the silicon oxide film is very high upon using the SF₆ gas rather than the O₂ gas, it can be noted that the resist selectivity is higher upon using the SF₆ gas rather than the O₂ gas.

Referring to FIG. 7 based on the above described experiment results, when using the SF₆ gas (white circle) as the additional gas, both the etch rate and the resist selectivity are higher in comparison with using the O₂ gas (black circle). Specifically, in either case of using the SF₆ gas (white circle) or the O₂ gas (black circle) as the additional gas, both the etch rate and the resist selectivity are gradually increased up to a certain flow rate according to the increase of the additional gas but the resist selectivity abruptly takes a decreasing trend when a flow rate of the additional gas exceeds a certain flow rate. Therefore, the flow rates (shown in FIG. 7 as plots enclosed by dashed-line circles) at the flow rate transition points are optimal flow rates at which both the etch rate and the resist selectivity have highest values. At this time, the respective flow rates of the additional gases, i.e., the optimal flow rates of the additional gases are 20 sccm of the O₂ gas and 11 sccm of the SF₆ gas, respectively. That is, the flow rate of the SF₆ gas is optimized at ½ of the flow rate of the O₂ gas. As such, by setting the flow rates of the additional gases based on the relationship between the etch rate and the resist selectivity, the optimal flow rates of the additional gases can be easily found.

Also, the etch rate at the optimal flow rates of the additional gases is 4000 angstrom/min when using the O₂ gas while it becomes an extremely high level exceeding 5000 angstrom/min when using the SF₆ gas. Further, the resist selectivity at this time is 13.0 when using the O₂ gas while it is 17.3 when using the SF₆ gas. That is, it can be noted that the resist selectivity is higher when using the SF₆ gas rather than the O₂ gas.

Moreover, in FIG. 7, the flow rates of the additional gases may be set in the range within which both the etch rate and the resist selectivity tend to increase. For example, when using the O₂ gas, the resist selectivity tends to decrease at which the etch rate is around 4000 angstrom/min. As a result, by setting the flow rate of the SF₆ gas to a range at which the etch rate is 4000 angstrom/min or more, both the etch rate and the resist selectivity can be higher when compared with using the O₂ gas in the prior art. In this way, the flow rates of the additional gases are set based on the relationship between the etch rate and the resist selectivity such that a suitable range for the flow rates of the additional gases can be easily found.

As such, it is considered that the increase of the etch rate when using the SF₆ gas as the additional gas rather than the O₂ gas can be attributed to a drastic increase of F relative to C when using the SF₆ gas than the O₂ gas, as described above, which effectively controls a film thickness of a deposit that is a fluorocarbon-based polymer (CF-based polymer). As such, by regulating the flow rate of the SF₆ gas, the film thickness of the deposit can be controlled.

Further, the reason for the increase of the resist selectivity in spite of using the SF₆ gas may be explained in the same manner as using the O₂ gas. That is, this is because oxygen contained in the silicon oxide film is sputtered out at an etch surface of the silicon oxide film so as to contribute to dissolve the deposit of the CF-based polymer while the deposit is not easily removed with ions impact at a surface of the photoresist film.

In addition, it is considered that the higher resist selectivity when using the SF₆ gas as the additional gas than using the O₂ gas can be attributed to S (sulfur) atoms contained in the SF₆ gas which creates a C—S combination in the deposit of the CF-based polymer such that the deposit is hardened to delay the etching on the surface of the photoresist film when compared with the etch surface of the silicon oxide film. As a result, when using the SF₆ gas, hardness of the deposit can be controlled by regulating the flow rate of the SF₆ gas. In this way, the resist selectivity can be higher when using the SF₆ gas than the O₂ gas.

As described above in detail, in the present embodiment, the SF₆ gas is added as the additional gas to the process gas containing the fluorocarbon-based gas that is an etch gas having a deposition property and the flow rate of the SF₆ gas is regulated. Accordingly, an etching on a film to be etched can be performed while controlling the film thickness of the deposit accumulated on the wafer and the hardness of the deposit. In this way, both the etch rate and the resist selectivity can be improved over the prior art such that holes or trenches having a high aspect ratio can be effectively formed over the prior art.

Further, a suitable range of the flow rate of the additional gas is different depending on the types of process gases. For example, when adding the SF₆ gas to the process gas containing C₄F₆ gas (22 sccm) and Ar gas (300 sccm) as described above, both the etch rate and the resist selectivity are improved at the flow rate of 11 sccm or less of the SF₆ gas, that is, at a flow rate of 50% or less with respect to the flow rate of the fluorocarbon-based gas. In this connection, when using gas other than the C₄F₆ gas as the additional gas, for example, using C₆F₆ having a lower F/C ratio than the C₄F₆ gas, the deposit becomes more than when using the C₄F₆ gas as shown in FIG. 2. Thus, a more flow rate of the SF₆ gas is required so as to appropriately control the deposit. However, as described above, the resist selectivity becomes deteriorated when the flow rate of the SF₆ gas is excessive and thus, it is preferable that the flow rate of the SF₆ gas is adequately set in the range of 70% or less with respect to the flow rate of the fluorocarbon-based gas.

As for the additional gas, in some embodiments, the O₂ gas may be further added to the SF₆ gas. In this way, a fine control of the film thickness of the deposit can be easily achieved by the flow rate of the O₂ gas. Specifically, since the O₂ gas has a lower removal capability against the deposit than the SF₆ gas, the fine control of the film thickness of the deposit can be easily realized by using the additional gas containing the O₂ gas.

Although the silicon oxide film is described in the present embodiment as an example of the silicon-containing oxide film serving as the film to be etched, it may also include an inorganic low-k film such as a carbon-containing silicon oxide (SiOC) film, a hydrogen-containing silicon oxide (SiOH) film, a fluorine-containing silicon oxide (SiOF) film, and the like. Also, the silicon oxide film may be constituted by a boron phosphosilicate glass (BPSG), a phosphosilicate glass (PSG), a tetra-ethoxy silane (TEOS), a thermal oxide (Th-OX), a spin-on-glass (SOG), or the like. Further, although the C₄F₆ gas is described as an example of the fluorocarbon-based gas serving as an etch gas having a deposition property, in some embodiments, another fluorocarbon-based gas such as C₄F₈, C₅F₈, C₆F₆, C₆F₁₂, and the like may be used.

While some preferable embodiments have been described with reference to the accompanying drawings, these embodiments have been presented by way of example only, and are not intended to limit the scope of the inventions. Indeed, the novel apparatus and method described herein may be embodied in a variety of other forms. Furthermore, various omissions, substitutions and changes in the form of the embodiments described herein may be made without departing from the spirit of the inventions.

For example, in the embodiments described herein, the plasma etching apparatus is described as a type in which the high-frequency power is applied to both the upper electrode and the lower electrode, but it is not limited thereto. The plasma etching apparatus, for example, may be a type in which the high-frequency power is applied to either the upper electrode or the lower electrode, or a type in which the high-frequency power of another frequency power is overlapped and applied to the lower electrode. Also, the plasma etching apparatus in accordance with the present invention may be applicable to various type of apparatus such as an electron cyclotron resonance (ECR) plasma etching apparatus, a helicon wave plasma etching apparatus, a transformer coupled plasma (TCP) type plasma etching apparatus, an inductively-couple type plasma etching apparatus, and the like.

The present invention is applicable to the plasma etching method and the plasma etching apparatus which are suitable for a plasma etching of an oxide film and the like, for example, a high aspect ratio contact (HARC) process.

What is claimed is:

1. A plasma etching method comprising:
disposing a substrate having a silicon-containing oxide film formed thereon in a process chamber;
introducing a process gas containing a fluorocarbon-based gas being an etch gas having a deposition property and SF₆ gas as an additional gas into the process chamber, thereby generating a plasma; and
etching the silicon-containing oxide film by using a resist pattern as a mask through the plasma,
wherein, based on a relationship between an etch rate and a resist selectivity that is changed with respect to a change in a flow rate of the additional gas, the flow rate of the additional gas is set to a range of the flow rate in which changes in the etch rate and the resist selectivity accompanying an increase of the flow rate of the additional gas tend to increase.

2. The method of claim 1, wherein the flow rate of the additional gas is set to a maximum value in the flow rate range, the maximum value corresponding to a transition point at which the change in the resist selectivity accompanying the increase in the flow rate of the additional gas transitions from an increased tendency to a decreased tendency.

3. The method of claim 1, wherein the flow rate of the additional gas is 70% or less of a flow rate of the fluorocarbon-based gas.

4. The method of claim 1, wherein O₂ gas is introduced as the additional gas into the process chamber in addition to the SF₆ gas.

5. The method of claim 1, further comprising:
evaporating a fluorocarbon-based liquid raw material used as a raw material of the fluorocarbon-based gas through an evaporator so as to be converted into the fluorocarbon-based gas, the fluorocarbon-based liquid raw material being in a liquid state at a room temperature; and
supplying the fluorocarbon-based gas to the process chamber.

6. A plasma etching apparatus that generates a plasma of gas in a process chamber and performs an etching on a silicon-containing oxide film formed on a substrate by using a resist pattern as a mask, the apparatus comprising:
a process gas supply mechanism configured to supply a process gas containing a fluorocarbon-based gas to the process chamber;
an additional gas supply mechanism configured to supply SF₆ gas as an additional gas to the process chamber; and
a control unit configured to control at least the process gas supply mechanism and the additional gas supply mechanism,
wherein the control unit is configured to introduce a process gas containing a fluorocarbon-based gas being an etch gas having a deposition property, and to introduce a SF₆ gas as an additional gas, into the process chamber, thereby generating a plasma, and control flow rates of the respective process gas and additional gas to respective predetermined values upon performing the etching on the silicon-containing oxide film by using the resist pattern as the mask, and
based on a relationship between an etch rate and a resist selectivity that is changed with respect to a change in a flow rate of the additional gas, the predetermined value of the additional gas is set to a range of the flow rate of the additional gas in which changes in the etch rate and the resist selectivity accompanying an increase in the flow rate of the additional gas tend to increase.
